(19) United States
(12) Patent Application Publication
(10) Pub. No.: US 2026/0171652 A1
(43) Pub. Date: Jun. 18, 2026

(54) COUPLER FOR ACQUIRING POWER FROM RF SIGNAL AND ELECTRONIC DEVICE HAVING SAME

(71) Applicant: Samsung Electronics Co., Ltd., Suwon-si (KR)

(72) Inventors: Sungjin AN, Suwon-si (KR); Hyoseok NA, Suwon-si (KR); Namjun CHO, Suwon-si (KR); Hyewon JO, Suwon-si (KR)

(21) Appl. No.: 19/457,482

(22) Filed: Jan. 23, 2026

Related U.S. Application Data
(63) Continuation of application No. PCT/KR2025/021708, filed on Dec. 15, 2025.

(30) Foreign Application Priority Data
Dec. 16, 2024 (KR) 10-2024-0187577
Jan. 16, 2025 (KR) 10-2025-0006470

(51) Int. Cl. H01Q 1/22; H05K 1/02; H05K 1/11

(52) U.S. Cl. CPC H01Q 1/2283; H05K 1/0243; H05K 1/115; H05K 2201/10098

(57) ABSTRACT

A coupler for acquiring the power of a radio frequency (RF) signal may include a printed circuit board (PCB); a first signal line built into the PCB, and a second signal line built into the PCB. The first signal line may include a first port, a second port, a first element, and a second element. The second signal line may include a third port, a fourth port, a third element, and a fourth element. The first layer of the PCB may include the first port; the third port; the first element of the first signal line extending from the first port; and the third element of the second signal line extending from the third port. The second layer of the PCB may include the second port; and the second element of the first signal line extending from the second port and connected to the first element through a first via. The third layer of the PCB may include the fourth port; and the fourth element of the second signal line extending from the fourth port and connected to the third element through a second via.

### CROSS-REFERENCE TO RELATED APPLICATIONS

This application is a continuation of International Application No. PCT/KR2025/021708 designating the United States, filed on Dec. 15, 2025, in the Korean Intellectual Property Receiving Office and claiming priority to Korean Patent Application Nos. 10-2024-0187577, filed on Dec. 16, 2024, and 10-2025-0006470, filed on Jan. 16, 2025, in the Korean Intellectual Property Office, the disclosures of each of which are incorporated by reference herein in their entireties.

### BACKGROUND

### Field

The disclosure relates to a coupler for acquiring power from a radio frequency (RF) signal and an electronic device having the same.

### Description of Related Art

A coupler may be placed adjacent to an RF signal line to sample the power of an RF signal transmitted and received through an antenna. The coupler may be embedded in a multi-layered PCB. Such a coupler may be referred to as a printed circuit board embedded solution (PEMS) coupler. Information on the power of an RF signal acquired through the coupler may be used in a process of calibrating the performance by inspecting the RF transmission and reception performance. An electronic device may perform its own calibration process using a coupler without the support of separate measuring equipment.

The above-described information is provided as a related art for the purpose of helping in understanding the disclosure. No assertion or determination is made as to whether any of the above is applicable as prior art related to the disclosure.

Due to the thickness deviation of the PCB, the accuracy of power detection may differ for each electronic device performing its own calibration processor. For example, in the process of manufacturing the PEMS coupler, the thickness of the dielectric between the layers of the PCB may deviate from the allowable tolerance. Since the thickness of the dielectric is inversely proportional to the capacitance, it may affect the coupling factor, which is a characteristic of the coupler.

### SUMMARY

Embodiments of the disclosure may provide a coupler robust to the thickness deviation of a PCB and capable of miniaturization, and an electronic device having the same. Accordingly, the electronic device may accurately detect the power of an RF signal from the coupler and perform an accurate calibration process by itself.

According to an example embodiment, a coupler configured to acquire a power of a radio frequency (RF) signal may include: a printed circuit board (PCB); a first signal line built into the PCB; and a second signal line built into the PCB. The first signal line may include a first port, a second port, a first element comprising a conductive material or a conductor, and a second element comprising a conductive material/conductor. The second signal line may include a third port, a fourth port, a third element comprising a conductive material/conductor, and a fourth element comprising a conductive material/conductor. The first layer of the PCB may include the first port; the third port; the first element of the first signal line extending from the first port; and the third element of the second signal line extending from the third port. The second layer of the PCB may include the second port; and the second element of the first signal line extending from the second port and connected to the first element through a first via. The third layer of the PCB may include the fourth port; and the fourth element of the second signal line extending from the fourth port and connected to the third element through a second via. At least a part of the first element, at least a part of the second element, and at least a part of the fourth element, when the plane is viewed in a first direction perpendicular to the plane of the PCB, may be aligned in a line while overlapping. The third element, when the plane is viewed in the first direction, may be located inside the first element without overlapping the first element. At least a part of the first element and at least a part of the third element may be aligned in a line.

According to an example embodiment, an electronic device including the coupler is provided. The electronic device may include: an antenna; a wireless communication circuit configured to receive an RF signal from the antenna through the first signal line and output an RF signal to the antenna; and a power detection circuit configured to detect power of the RF signal output from the wireless communication circuit to the antenna through the second signal line.

According to various example embodiments of the disclosure, the PEMS coupler has a structure robust to the thickness deviation of the PCB. An electronic device having such a coupler is provided. The electronic device may accurately detect the power of an RF signal from the coupler and perform an accurate calibration process by itself. In addition, various effects that are directly or indirectly identified through the disclosure may be provided.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram illustrating an example electronic device in a network environment according to various embodiments;

FIG. 2 is a diagram illustrating an example configuration of an electronic device having a PEMS coupler according to various embodiments;

FIG. 3 is a diagram illustrating example power extraction in a PEMS coupler according to various embodiments;

FIGS. 4A and 4B are diagrams illustrating an example coupling structure applicable to a PEMS coupler according to various embodiments;

FIGS. 5A, 5B, 5C, 5D, 5E, and 5F are diagrams illustrating a PEMS coupler having a coupling structure robust to thickness deviation according to various embodiments;

FIG. 6 is a perspective view illustrating an example of a coupling structure applicable to a PEMS coupler according to various embodiments;

FIG. 7A is a graph illustrating a relationship between a frequency and a power ratio in a PEMS coupler having the coupling structure of FIG. 6 according to various embodiments; and

FIG. 7B is a graph illustrating a relationship between a frequency and a power ratio in a PEMS coupler having the coupling structure of FIG. 5A according to various embodiments.

Hereinafter, various example embodiments of the disclosure will be described in greater detail with reference to the drawings. However, the disclosure may be implemented in various different forms and is not limited to the various example embodiments described herein. In relation to the description of the drawings, the same or similar reference numerals may be used for the same or similar components. In addition, in the drawings and related descriptions, descriptions of well-known functions and configurations may be omitted for clarity and conciseness.

### DETAILED DESCRIPTION

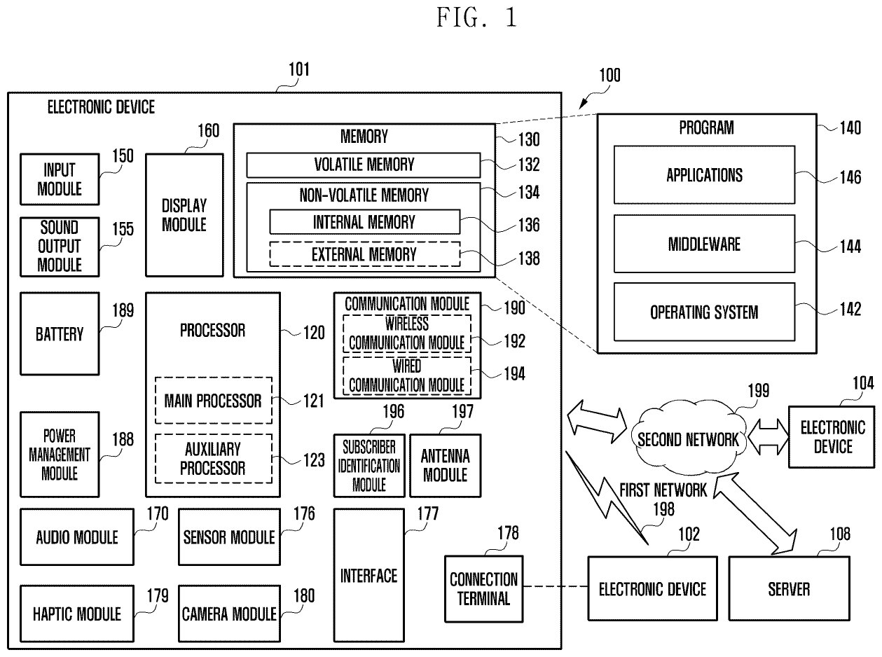

FIG. 1 is a block diagram illustrating an example electronic device 101 in a network environment 100 according to various embodiments. Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121. Thus, the processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™ wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of lms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

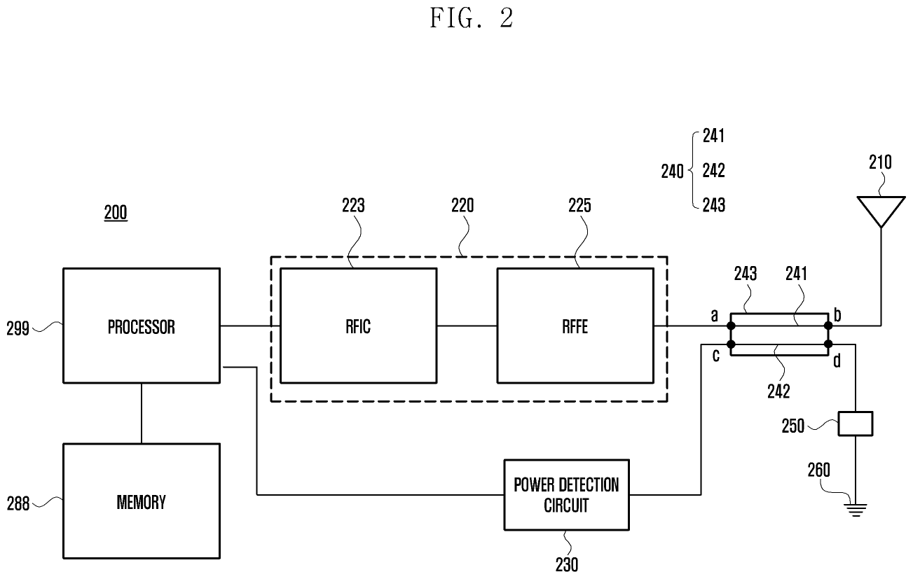

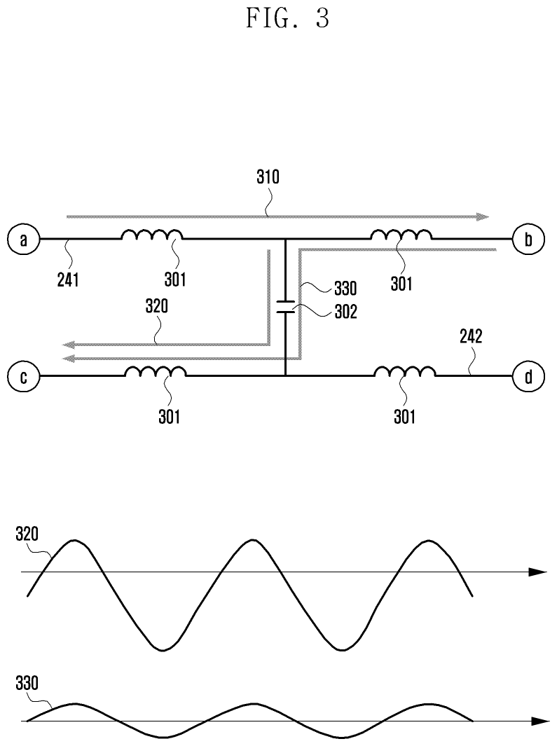

FIG. 2 is a block diagram illustrating an example configuration of an electronic device 200 having a PEMS coupler 240 according to various embodiments. FIG. 3 is a diagram illustrating example power extraction in the PEMS coupler 240 according to various embodiments.

Referring to FIG. 2, the electronic device 200 may include an antenna 210, a wireless communication circuit 220, a power detection circuit 230, a PEMS coupler 240, a memory 288, and a processor (e.g., including processing circuitry) 299.

Instructions may be stored in the memory 288. Some of the instructions may be stored in the memory 288 and others may be stored in the internal memory of the processor 299. The instructions, when executed by the processor 299, may cause the electronic device 200 to perform a given operation (e.g., a calibration process using power information acquired through the power detection circuit 230).

The processor 299 (e.g., the processor 120 of FIG. 1) may include a communication processor (CP) and an application processor (AP). The CP, together with the AP, may be configured on one chip or included in one package. The description of processor 120 above applies equally to the processor 299.

The wireless communication circuit 220 may receive a digital signal from the processor 299, convert the digital signal into an RF signal, and output the RF signal to the antenna 210. The wireless communication circuit 220 may receive an RF signal from the antenna 210 and convert the RF signal into a digital signal to output the digital signal to the processor 299. In an embodiment, the wireless communication circuit 220 may include a radio frequency integrated circuit (RFIC) 223 and a radio frequency front end (RFFE) 225.

The RFIC 223 may receive a digital signal from the processor 299 (e.g., a CP), convert the digital signal into an analog signal (hereinafter, a baseband signal) of a specified baseband, and convert the received baseband signal into an RF signal of a specified frequency band based on the control of the processor 299 (e.g., a CP). For example, the RFIC 223 may generate an RF signal by mixing a reference frequency signal generated by a local oscillator (LO) with a baseband signal. The RFIC 223 may output the RF signal to the antenna 210 through the RFFE 225. The RFIC 223 may receive an RF signal from the antenna 210 through the RFFE 225 and convert the RF signal into a baseband signal. For example, the RFIC 223 may generate a baseband signal by combining the reference frequency signal generated by the LO with the RF signal. The RFIC 223 may convert the baseband signal into a digital signal and output the digital signal to the processor 299 (e.g., a CP).

The power detection circuit 230 may detect the power of an RF signal (hereinafter, a transmitted (Tx) RF signal) output from the wireless communication circuit 220 to the antenna 210 through the PEMS coupler 240. The power detection circuit 230 may provide information on the detected power to the processor 299. For example, the power detection circuit 230 may receive an RF signal from the PEMS coupler 240 and convert the received RF signal into a digital signal and output the same to the processor 299. According to an embodiment, the power detection circuit 230 may be included in the wireless communication circuit 220 (e.g., the RFIC 223).

The PEMS coupler 240 may include a first signal line 241, a second signal line 242, and a PCB 243. The PCB 243 may have a multi-layered structure. The first signal line 241 and the second signal line 242 may be configured on the PCB 243. A port a, which is one end of the first signal line 241, may be connected to the RFFE 225 of the wireless communication circuit 220, and a port b, which is the other end of the first signal line 241, may be connected to the antenna 210. A port c, which is one end of the second signal line 242, may be connected to the power detection circuit 230, and a port d, which is the other end of the second signal line 242, may be connected to ground 260 of the electronic device 200. A resistive element (e.g., resistor or other circuitry (e.g., capacitor, inductor, or the like, having resistance) 250 may be placed between the ground 260 and the port d so that the RF signal extracted from the PEMS coupler 240 flows to the power detection circuit 230 through an electrical coupling between the first signal line 241 and the second signal line 242. The resistive element 250 may be mounted on the surface of the PCB 243.

Referring to FIG. 3, an RF signal 310 input to port a of the first signal line 241 may be output to the antenna 210 through the port b. When the RF signal 310 flows through the first signal line 242, an incident wave 320 and a reflected wave 330 may be generated in the PEMS coupler 240 by electrical coupling (e.g., inductive coupling 301 and capacitive coupling 302). The incident wave 320 and the reflected wave 330 may flow to the power detection circuit 230 through the port c of the second signal line 242. The accuracy of power detection may be determined by the difference between the power of the incident wave 310 and the power of the reflected wave 330. The lower the power of the reflected wave 330, the higher the accuracy may be.

In the PCB 243, the two signal lines 241 and 242 may be formed on the PCB 243 in a structure that may reduce the effect of the thickness between the layers on the accuracy of power detection. As an embodiment for this structure, the second signal line 242 may be partially formed in multiple layers on the PCB 243. At least a part of the first signal line 241 may be formed on the same layer as a part of the second signal line 242. Accordingly, the size of the PEMS coupler 240 may be reduced.

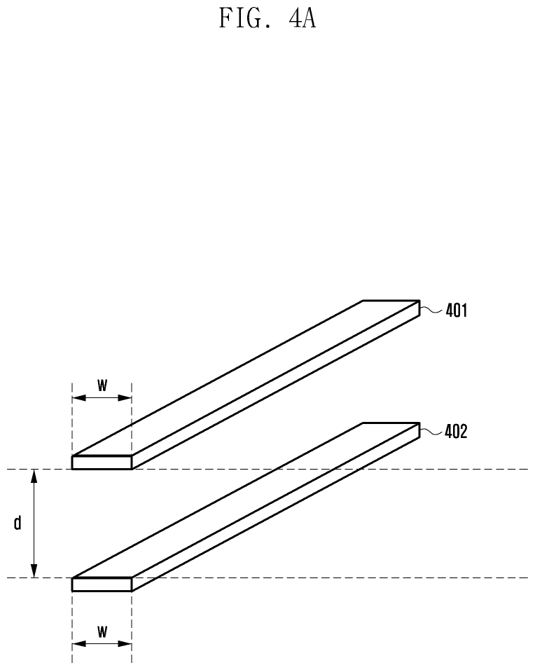

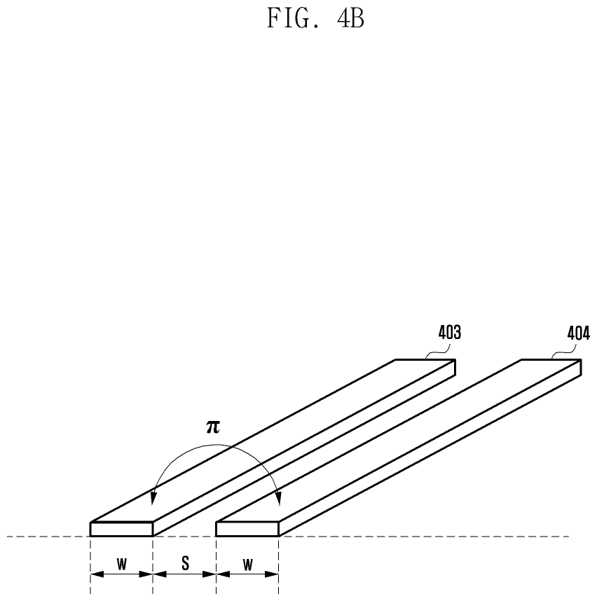

FIGS. 4A and 4B are diagrams illustrating an example coupling structure applicable to a PEMS coupler (e.g., the PEMS coupler 240 of FIG. 2) according to various embodiments.

Referring to FIG. 4A, a first conductive line 401 (e.g., a part of the first signal line 241) and a second conductive line 402 (e.g., a part of the second signal line 242) may be formed on different layers, respectively. The power of the RF signal flowing through the first conductive line 401 may be transmitted to the second conductive line 402 by electrical coupling (e.g., inductive coupling 301 and capacitive coupling 302). Capacitance C1 between the first conductive line 401 and the second conductive line 402 may be defined as in Equation 1 below. In the equation, W is the width of the two conductive lines 401 and 402, and d is the distance between the two conductive lines 401 and 402. ¿ is a predetermined (e.g., specified) constant value. Referring to Equation 1, C1 is affected by d. d may vary depending on the thickness of the dielectric located between the layers. As the thickness of the dielectric decreases, C1 increases, and as the thickness of the dielectric increases, C1 decreases. Therefore, the deviation of the thickness may be a factor of lowering the reliability of the detected power value using the coupler.

$$C 1 = \frac{ε W}{d} \qquad [ Equation 1 ]$$

Equation 1 is merely an example to help understanding, and the disclosure may not be limited thereto. For example, Equation 1 may be modified, applied, or extended in various ways.

The coupling coefficient may be increased by a phenomenon in which the magnetic field line bends toward the edge, e.g., the fringing effect. The fringing effect may occur between conductive lines formed in the same layer.

Referring to FIG. 4B, a third conductive line 403 (e.g., a part of the first signal line 241) and a fourth conductive line 404 (e.g., a part of the second signal line 242) may be formed on the same layer. Coupling according to the fringe effect of the two conductive lines 403 and 404 located on the same layer and adjacent to each other may increase the transmission efficiency of energy (e.g., power). Capacitance C2 between the third conductive line 403 and the fourth conductive line 404 may be defined as in Equation 2 below. In the equation, W is the width of the two conductive lines 403 and 404, and S is the distance between the two conductive lines 403 and 404. In( ) is a natural logarithmic function, ε is a predetermined constant value, and x is the ratio of the circumference of a circle to its diameter.

$$C 2 = \frac{ε}{π} ln ( 1 + \frac{2 W}{S} ) \qquad [ Equation 2 ]$$

Equation 2 is merely an example to help understanding, and the disclosure may not be limited thereto. For example, Equation 2 may be modified, applied, or extended in various ways.

C2 is affected by S. When S decreases, C2 increases, and when S increases, C2 decreases. Therefore, the deviation of the distance “S” between the two conductive lines 403 and 404 may be a factor that reduces the reliability of the power value detected using the coupler.

As described above, the PEMS coupler according to an embodiment of the disclosure may be robust to the deviation of thickness (e.g., d as described above) and/or the deviation of distance (e.g., S as described above) by having a coupling structure having a first conductive line 401, a second conductive line 402 located on a different layer from the first conductive line 401, and a fourth conductive line 404 located on the same layer as the first conductive line 401 (e.g., third conductive line 403). Therefore, the reliability of the power value detected using the coupler may be high.

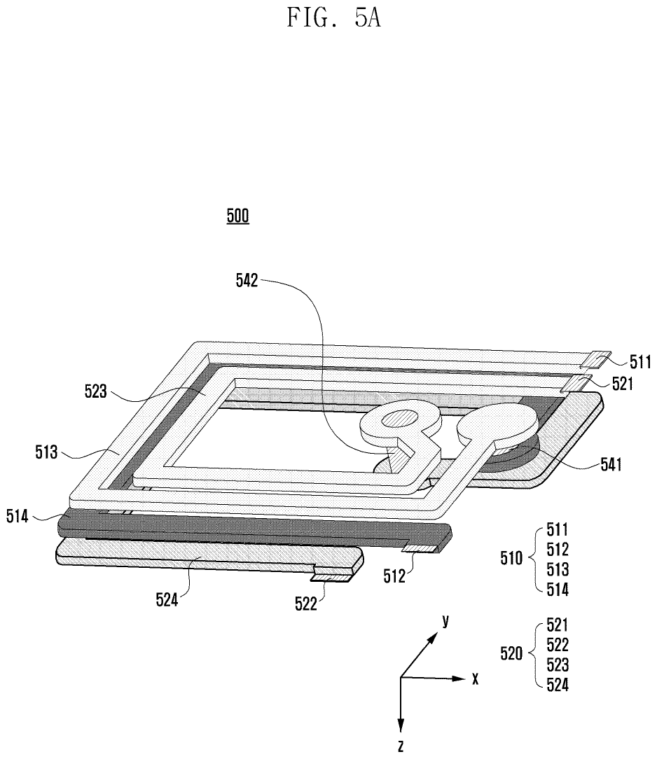

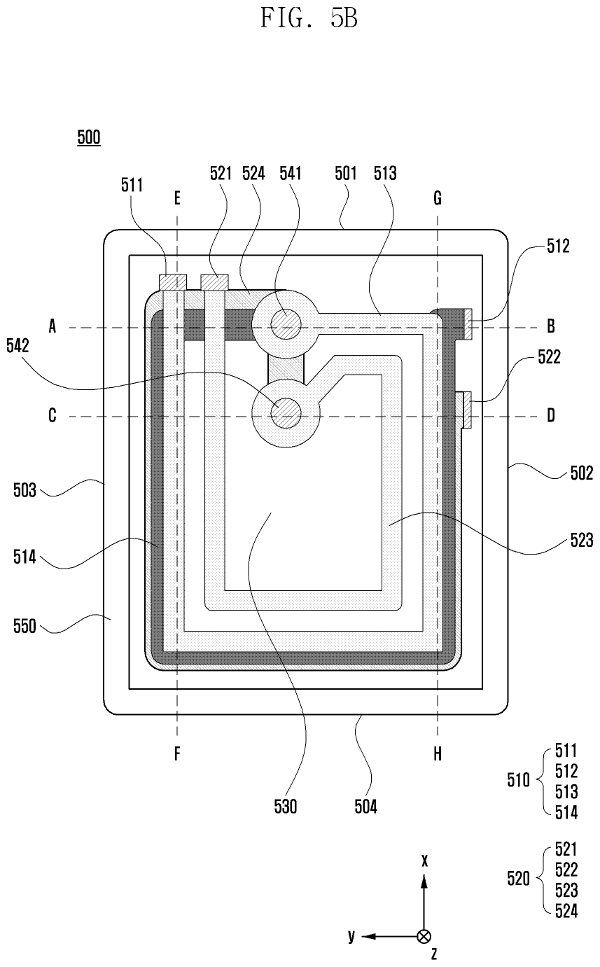

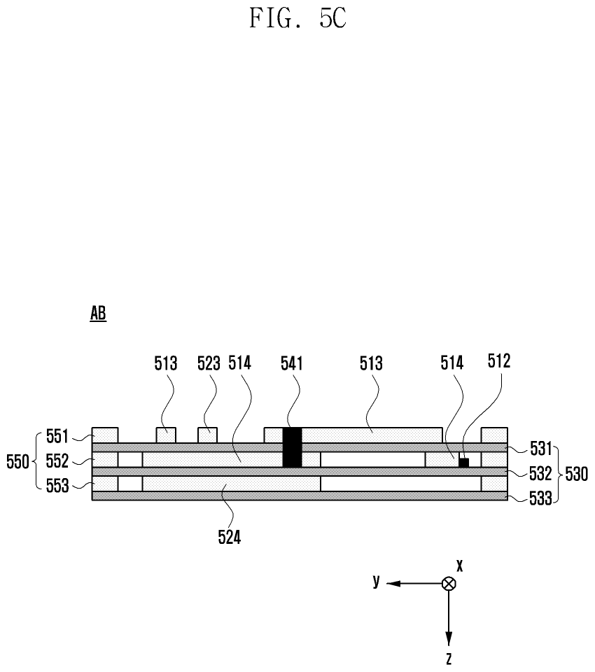

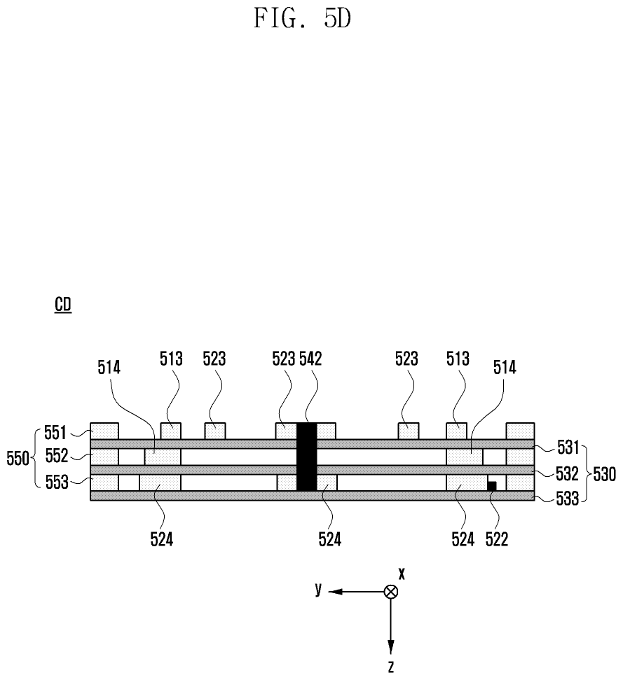

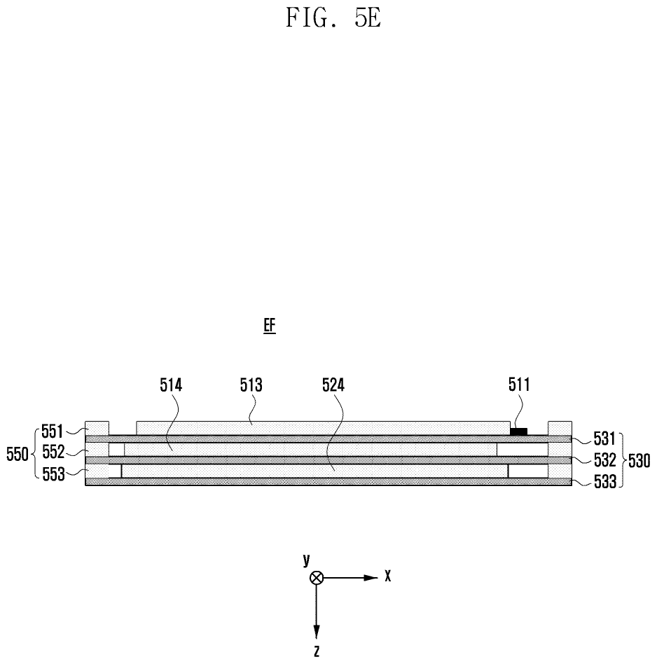

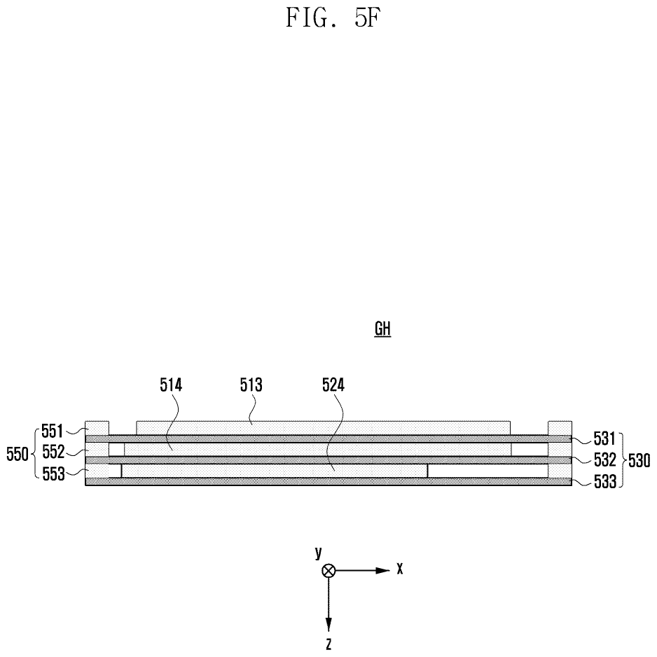

FIGS. 5A, 5B, 5C, 5D, 5E, and 5F are diagrams illustrating an example PEMS coupler 500 having a coupling structure robust to thickness deviation according to various embodiments. For example, FIG. 5A is a perspective view of the PEMS coupler 500 according to various embodiments. FIG. 5B is a diagram illustrating a front view of the PEMS coupler 500 according to various embodiments. FIG. 5C is a cross-sectional view of the PEMS coupler 500 taken in the AB direction according to various embodiments. FIG. 5D is a cross-sectional view illustrating the PEMS coupler 500 taken in the CD direction according to various embodiments. FIG. 5E is a cross-sectional view illustrating the PEMS coupler 500 taken in the EF direction according to various embodiments. FIG. 5F is a cross-sectional view illustrating the PEMS coupler 500 taken in the GH direction according to various embodiments. The PEMS coupler 500 may include a first signal line 510, a second signal line 520, and a multi-layered PCB 530 (refer to FIGS. 5C, 5D, 5E and 5F).

The first signal line 510 may include a first port 511 and a second port 512. One of the first port 511 and the second port 512 may be a port a (refer to FIG. 2) connected to the wireless communication circuit 220 and the other may be a port b (refer to FIG. 2) connected to the antenna 210.

The second signal line 520 may include a third port 521 and a fourth port 522. One of the third port 521 and the fourth port 522 may be a port c (refer to FIG. 2) connected to the power detection circuit 230 and the other may be a port d (refer to FIG. 2) connected to the ground 260.

In the first signal line 510, a first element (e.g., portion of the first signal line including a conductive material or conductor) 513 and the first port 511 may be formed on a first layer (or a substrate) 531 of the PCB 530. The first element 513 may extend from the first port 511 and may be connected to a second element 514 in the second signal line 520 through a first via 541. According to an embodiment, the first port 511 may be placed on another layer (e.g., a second layer 532, a third layer 533, or another layer not shown) rather than the first layer 531, and may thus be connected to the first element 513 through another via.

In the first signal line 510, the second element 514 and the second port 512 may be formed on the second layer 532 of the PCB 530. The second element 514 may extend from the second port 512 and may be connected to the first element 513 through the first via 541. According to an embodiment, the second port 512 may be placed on another layer (e.g., the first layer 531, the third layer 533, or another layer) rather than the second layer 532, and may thus be connected to the second element 514 through another via.

In the second signal line 520, a third element 523 and the third port 521 may be formed on the first layer 531 of the PCB 530. The third element 523 may extend from the third port 521 and may be connected to a fourth element 524 in the second signal line 520 through a second via 542. According to an embodiment, the third port 521 may be placed on another layer (e.g., the second layer 532, the third layer 533, or another layer) rather than the first layer 531, and may thus be connected to the third element 523 through another via.

In the second signal line 520, the fourth element 524 and the fourth port 522 may be formed in the third layer 533 of the PCB 530. The fourth element 524 may extend from the fourth port 522 and may be connected to the third element 523 in the second signal line 520 through the second via 542. According to an embodiment, the fourth port 522 may be placed on another layer (e.g., the first layer 531, the second layer 532, or another layer) rather than the third layer 533, and may thus be connected to the fourth element 524 through another via.

The PEMS coupler 500 may include a conductive pattern 550 (e.g., a resistive element 250 of FIG. 2) for isolation from the neighboring electronic components. The conductive pattern 550 may be connected to the fourth port 522 and, as illustrated in FIG. 5B, may have a closed loop (e.g., a caging structure) surrounding the first signal line 510 and the second signal line 520. For example, the conductive pattern 550 may include a first conductive pattern 551 placed on the first layer 531, a second conductive pattern 552 placed on the second layer 532, and a third conductive pattern 553 placed on the third layer 533, as illustrated in FIGS. 5C, 5D, 5E, and 5F. The conductive patterns of each layer may be connected to each other through vias.

The elements 513, 514, 523, and 524 may be wound clockwise or counterclockwise when viewed in a plane in a direction (e.g., z-axis direction) perpendicular to the plane (e.g., x-y plane) of the PCB 530.

Referring to FIG. 5B, the PCB 530 may have a rectangular shape. For example, the PCB 530 may have has a first side (or upper side) 501, a second side (or right side) 502 perpendicular to the first side 501, a third side (or left side) 503 parallel to the second side 502, and a fourth side (or lower side) 504 parallel to the first side 501. The first port 511 and the first via 541 may be placed on the first layer 531 adjacent to the first side 501. The first element 513 may extend from the first port 511 to the first via 541 along the third side 503, the fourth side 504, and the second side 502.

The third port 521 may be placed on the first layer 531 between the first port 511 and the first via 541 and adjacent to the first side 501. The second via 542 may be placed on the first layer 531 adjacent to the first via 541 and closer to the fourth side 504 compared to the first via 541. The third element 523 may extend from the third port 521 to the second via 542 along the third side 503, the fourth side 504, and the second side 502. The third element 523 may be located inside the first element 513 as shown.

The second port 512 may be placed on the second layer 532 adjacent to the second side 502. The fourth port 522 may be placed on the third layer 533 adjacent to the second side 502 and closer to the fourth side 504 compared to the second port 512. The second element 514 may extend from the first via 541 to the second port 512 along the third side 503, the fourth side 504, and the second side 502. The fourth element 524 may extend from the second via 542 to the fourth port 522 along the third side 503, the fourth side 504, and the second side 502.

At least a part of the first element 513, at least a part of the second element 514, and at least a part of the fourth element 524 may be aligned in a line while overlapping when viewed in a plane in a first direction (e.g., z-axis direction) perpendicular to the plane (e.g., x-y plane) of the PCB 500. Referring to FIG. 5B, the left part of the first element 513, the left part of the second element 514, and the left part of the fourth element 524 may extend along the left side 503 (e.g., in a straight line parallel to the left side 503) while overlapping when viewed in the plane of the PCB 530 in the first direction. The lower part of the first element 513, the lower part of the second element 514, and the lower part of the fourth element 524 may extend along the lower side 504 (e.g., in a straight line parallel to the lower side 504) while overlapping when viewed in the plane of the PCB 530 in the first direction. The right part of the first element 513, the right part of the second element 514, and the right part of the fourth element 524 may extend along the right side 502 (e.g., in a straight line parallel to the right side 502) while overlapping when viewed in the plane of the PCB 530 in the first direction.

The third element 523 may be located inside the first element without overlapping the first element 513 when viewed in the plane of the PCB 530 in the first direction. At least a part of the first element 513 and at least a part of the third element 523 may be aligned in a line. Referring to FIG. 5B, the left part of the third element 523 may be located inside the PCB 530 than the left part of the first element 513, and may extend in a straight line parallel to the left part of the first element 513. The lower part of the third element 523 may be located inside the PCB 530 than the lower part of the first element 513 and may extend in a straight line parallel to the lower part of the first element 513. The right part of the third element 523 may be located inside the PCB 530 than the right part of the first element 513 and may extend in a straight line parallel to the right part of the first element 513.

One or more layers may be located between the first layer 531 and the second layer 532 and/or between the second layer 532 and the third layer 533.

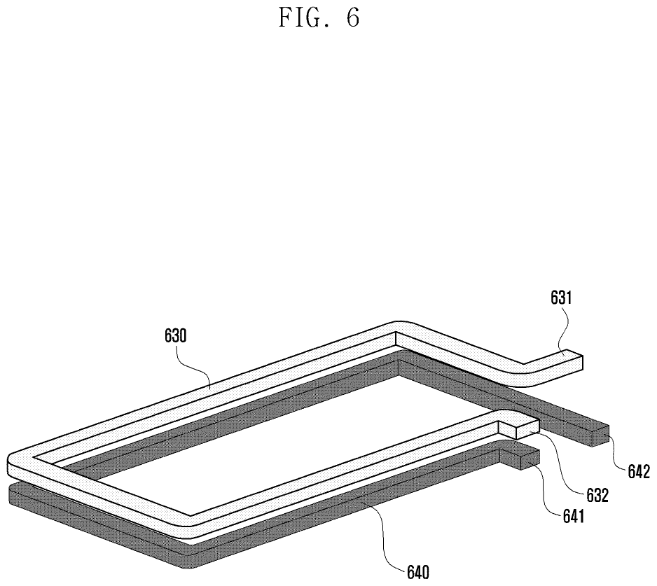

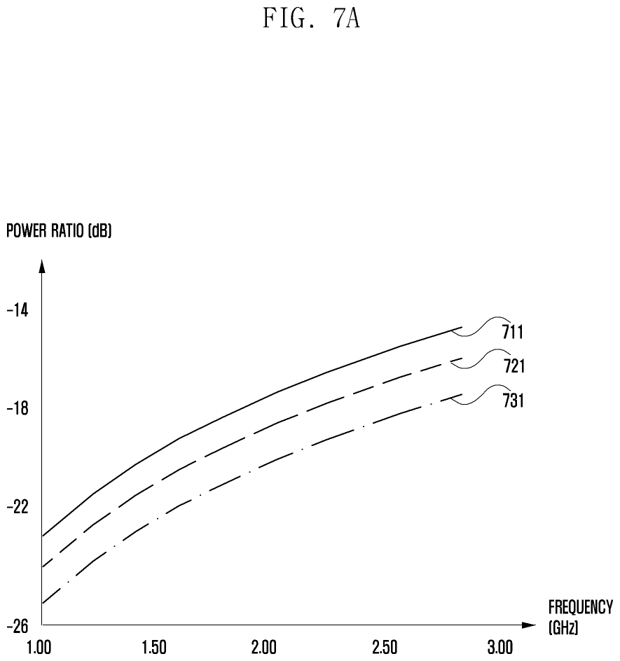

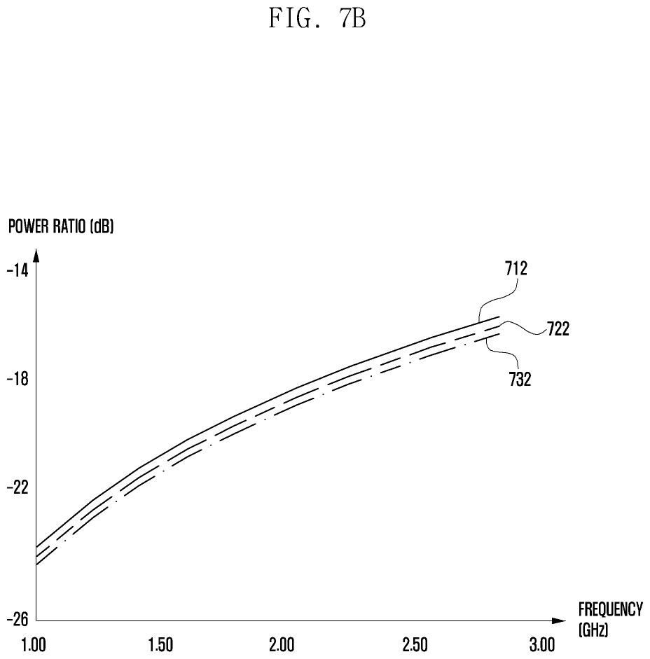

FIG. 6 is a perspective view illustrating an example of a coupling structure applicable to a PEMS coupler according to various embodiments. FIG. 7A is a graph illustrating a relationship between a frequency and a power ratio in the PEMS coupler having the coupling structure of FIG. 6 according to various embodiments. FIG. 7B is a graph illustrating a relationship between a frequency and a power ratio in the PEMS coupler 500 having the coupling structure of FIG. 5A according to various embodiments. In FIGS. 7A and 7B, the y-axis represents the ratio of the power detected using the power detection circuit to the power of the RF signal input to the PEMS coupler in the wireless communication circuit, and the magnitude of the power ratio is expressed in decibels. In FIGS. 7A and 7B, the x-axis represents the frequency of the RF signal input to the corresponding PEMS coupler in the wireless communication circuit, and the unit is GHz.

Referring to FIG. 6, the PEMS coupler may include a third signal line 630 placed on the first layer on a multi-layered PCB and a fourth signal line 640 placed on the second layer on the PCB. One end 631 of the third signal line 630 may be connected to a wireless communication circuit (e.g., the wireless communication circuit 220), and the other end 632 may be connected to an antenna (e.g., the antenna 210). One end 641 of the fourth signal line 640 may be connected to a power detection circuit (e.g., the power detection circuit 230) and the other end 642 may be connected to ground (e.g., the ground 260). For example, the other end 642 may be connected to ground through a resistive element (e.g., the resistive element 250). The third signal line 630 and the fourth signal line 640 may have a shape similar to that illustrated in FIG. 5A, and may be aligned in a line while overlapping when viewed in a plane perpendicular to the plane of the PCB.

Referring to FIGS. 6 and 7A, reference numeral 711 indicates the relationship between the frequency and power ratio when the distance between the third signal line 630 and the fourth signal line 640 (e.g., the thickness of the dielectric existing between the two signal lines 630 and 640) is the first distance value. Reference numeral 721 indicates the relationship between the frequency and power ratio when the distance between the third signal line 630 and the fourth signal line 640 is the second distance value (>the first distance value). Reference numeral 731 indicates the relationship between the frequency and power ratio when the distance between the third signal line 630 and the fourth signal line 640 is the third distance value (>the second distance value). It may be identified from FIG. 7A that the coupling coefficient decreases as the distance increases.

Referring to FIG. 7B, reference numeral 712 indicates the relationship between the frequency and power ratio when the distance between the first signal line 510 and the second signal line 520 (e.g., the thickness of the second layer 532) is the first distance value. Reference numeral 722 denotes the relationship between the frequency and power ratio when the distance between the first signal line 510 and the second signal line 520 is the second distance value (>the first distance value). Reference numeral 732 indicates the relationship between the frequency and the power ratio when the distance between the first signal line 510 and the second signal line 520 is the third distance value (>the second distance value). It may be identified from FIG. 7B that the coupling coefficient decreases as the distance increases. In addition, it may be identified from FIG. 7B that the coupling structure of FIG. 5A has a smaller deviation in the coupling coefficient compared to the coupling structure of FIG. 6. That is, it may be identified from FIGS. 7A and 7B that the coupling structure of FIG. 5A is a structure that is robust to thickness deviation compared to the coupling structure of FIG. 6.

According to an example embodiment, a coupler (e.g., the PEMS coupler 240 or the PEMS coupler 500) for acquiring the power of a radio frequency (RF) signal may include a printed circuit board (PCB); a first signal line built into the PCB; and a second signal line built into the PCB. The first signal line may include a first port, a second port, a first element, and a second element. The second signal line may include a third port, a fourth port, a third element, and a fourth element. The first layer of the PCB may include the first port; the third port; the first element of the first signal line extending from the first port; and the third element of the second signal line extending from the third port. The second layer of the PCB may include the second port; and the second element of the first signal line extending from the second port and connected to the first element through a first via. The third layer of the PCB may include the fourth port; and the fourth element of the second signal line extending from the fourth port and connected to the third element through a second via. At least a part of the first element, at least a part of the second element, and at least a part of the fourth element, when the plane is viewed in a first direction perpendicular to the plane of the PCB, may be aligned in a line while overlapping. The third element, when the plane is viewed in the first direction, may be located inside the first element without overlapping the first element. At least a part of the first element and at least a part of the third element may be aligned in a line.

According to an example embodiment, an electronic device (e.g., the electronic device 200) including the coupler is provided. The electronic device may include an antenna; a wireless communication circuit configured to receive an RF signal from the antenna through the first signal line and output an RF signal to the antenna; and a power detection circuit configured to detect power of the RF signal output from the wireless communication circuit to the antenna through the second signal line.

The first element may be formed on the first layer in a form that is wound clockwise or counterclockwise from the first port to the first via when the plane is viewed in the first direction. The third element may be formed on the first layer in a form that is wound in the same direction as the winding direction of the first element from the third port to the second via when the plane is viewed in the first direction.

The ground may include a conductive pattern formed on at least one layer of the PCB.

The conductive pattern may be located outside the first signal line and the second signal line when the plane is viewed in the first direction.

The conductive pattern may have a closed loop shape surrounding the first signal line and the second signal line.

The PCB may have a rectangular shape. The first port and the third port may be located adjacent to the first side of the rectangle. The second port and the fourth port may be located adjacent to the second side perpendicular to the first side.

The first port may be connected to the wireless communication circuit and the second port may be connected to the antenna. The third port may be connected to the power detection circuit and the fourth port may be connected to the ground.

In the above description, the prefixes “first”, “second”, and “third” are only used to distinguish components of the same name, and do not have any special meaning in themselves, such as importance or order.

In the disclosure, the term “connection” may refer, for example, not only to a direct connection between components, but may also indicate that there are other components (e.g., a resistor, an inductor, etc.) between the components and they are electrically connected.

The electronic device according to various embodiments may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element.

As used in connection with various embodiments of the disclosure, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been illustrated and described with reference to various example embodiments, it will be understood that the various example embodiments are intended to be illustrative, not limiting. It will be further understood by those skilled in the art that various modifications, alternatives and/or variations of the various example embodiments may be made without departing from the true technical spirit and full technical scope of the disclosure, including the appended claims and their equivalents. It will also be understood that any of the embodiment(s) described herein may be used in conjunction with any other embodiment(s) described herein.

What is claimed is:

1. An electronic device comprising:
an antenna;
a printed circuit board (PCB) including a first signal line and a second signal line;
a wireless communication circuit configured to receive an RF signal from the antenna through the first signal line and output an RF signal to the antenna; and
a power detection circuit configured to detect power of the RF signal output from the wireless communication circuit to the antenna through the second signal line,
wherein the first signal line comprises a first port, a second port, a first element comprising a conductive material, and a second element comprising a conductive material, and at least one of the first port and the second port is connected to the antenna and the other is connected to the wireless communication circuit,
wherein the second signal line comprises a third port, a fourth port, a third element comprising a conductive material, and a fourth element comprising a conductive material, and at least one of the third port and the fourth port is connected to the power detection circuit and the other is connected to the ground of the electronic device,
wherein a first layer of the PCB comprises the first port; the third port; the first element of the first signal line extending from the first port; and the third element of the second signal line extending from the third port,
wherein a second layer of the PCB comprises the second port; and the second element of the first signal line extending from the second port and connected to the first element through a first via,
wherein a third layer of the PCB comprises the fourth port; and the fourth element of the second signal line extending from the fourth port and connected to the third element through a second via,
wherein at least a part of the first element, at least a part of the second element, and at least a part of the fourth element, when the plane is viewed in a first direction perpendicular to the plane of the PCB, are aligned in a line while overlapping,
wherein the third element, when the plane is viewed in the first direction, is located inside the first element without overlapping the first element, and
wherein at least a part of the first element and at least a part of the third element are aligned in a line.

2. The electronic device of claim 1,
wherein the first element is formed on the first layer and is wound clockwise or counterclockwise from the first port to the first via when the plane is viewed in the first direction, and
wherein the third element is formed on the first layer and is wound in the same direction as the winding direction of the first element from the third port to the second via when the plane is viewed in the first direction.

3. The electronic device of claim 1,
wherein the ground comprises a conductive pattern formed on at least one layer of the PCB.

4. The electronic device of claim 3,
wherein the conductive pattern is located outside the first signal line and the second signal line when the plane is viewed in the first direction.

5. The electronic device of claim 4,
wherein the conductive pattern has a closed loop shape substantially surrounding the first signal line and the second signal line.

6. The electronic device of claim 1,
wherein the PCB has a rectangular shape,
wherein the first port and the third port are adjacent to the first side of the rectangle, and
wherein the second port and the fourth port are adjacent to the second side perpendicular to the first side.

7. The electronic device of claim 1,
wherein the first port is connected to the wireless communication circuit and the second port is connected to the antenna, and
wherein the third port is connected to the power detection circuit and the fourth port is connected to the ground.

8. A coupler configured to acquire a power of a radio frequency (RF) signal, the coupler comprising:
a printed circuit board (PCB);
a first signal line built into the PCB; and
a second signal line built into the PCB,
wherein the first signal line comprises a first port, a second port, a first element comprising a conductive material, and a second element comprising a conductive material,
wherein the second signal line comprises a third port, a fourth port, a third element comprising a conductive material, and a fourth element comprising a conductive material,
wherein a first layer of the PCB comprises the first port; the third port; the first element of the first signal line extending from the first port; and the third element of the second signal line extending from the third port,
wherein a second layer of the PCB comprises the second port; and the second element of the first signal line extending from the second port and connected to the first element through a first via,
wherein a third layer of the PCB comprises the fourth port; and the fourth element of the second signal line extending from the fourth port and connected to the third element through a second via,
wherein at least a part of the first element, at least a part of the second element, and at least a part of the fourth element, when the plane is viewed in a first direction perpendicular to the plane of the PCB, are aligned in a line while overlapping,
wherein the third element, when the plane is viewed in the first direction, is located inside the first element without overlapping the first element, and
wherein at least a part of the first element and at least a part of the third element are aligned in a line.

9. The coupler of claim 8,
wherein the first element is formed on the first layer and is wound clockwise or counterclockwise from the first port to the first via when the plane is viewed in the first direction, and
wherein the third element is formed on the first layer and is wound in the same direction as the winding direction of the first element from the third port to the second via when the plane is viewed in the first direction.

10. The coupler of claim 8, further comprising a conductive pattern formed on at least one layer of the PCB and connected to the third port or the fourth port.

11. The coupler of claim 10,
wherein the conductive pattern is located outside the first signal line and the second signal line when the plane is viewed in the first direction.

12. The coupler of claim 11,
wherein the conductive pattern has a closed loop shape substantially surrounding the first signal line and the second signal line.

13. The coupler of claim 8,
wherein the PCB has a rectangular shape,
wherein the first port and the third port are adjacent to the first side of the rectangle, and
wherein the second port and the fourth port are adjacent to the second side perpendicular to the first side.

14. The coupler of claim 8,
wherein the first port is connected to the wireless communication circuit and the second port is connected to the antenna, and
wherein the third port is connected to the power detection circuit and the fourth port is connected to the ground.
